(19) United States
(12) Patent Application Publication
(10) Pub. No.: US 2023/0297174 A1
(43) Pub. Date: Sep. 21, 2023

(54) MOUSE SHELL WITH COOLING TOUCH

(71) Applicant: Primax Electronics Ltd., Taipei (TW)

(72) Inventors: Han-Pin Kao, Taipei (TW); Chun-Che Wu, Taipei (TW)

(21) Appl. No.: 17/750,161

(22) Filed: May 20, 2022

(30) Foreign Application Priority Data
Mar. 18, 2022 (TW) 111110208

(51) Int. Cl. G06F 3/0354; H05K 7/20

(52) U.S. Cl. CPC G06F 3/03543; H05K 7/2039; B22F 1/09

(57) ABSTRACT

The present invention provides a mouse shell with cooling touch, which includes a plastic material and a thermally conductive material, and the thermally conductive material is selected from the group consisting of thermally conductive powders, a thermally conductive object and a combination thereof. The thermally conductive powders are dispersed in the plastic material. The thermally conductive object is covered by the plastic material, or the thermally conductive object is attached beneath the plastic material. The thermally conductive powders are selected from the group consisting of metal powders, alloy powders, ceramic powders and combinations thereof. The thermally conductive object is selected from a metal object, an alloy object, a ceramic object and combinations thereof.

### FIELD OF THE INVENTION

The present invention relates to a mouse shell with cooling touch.

### BACKGROUND OF THE INVENTION

Most of existing mouse shells are made of plastic materials, which do not have cooling touch. However, some users may feel stuffy and uncomfortable when using the mouse. Therefore, there is a need for a mouse with cooling touch to solve the above issues.

### SUMMARY OF THE INVENTION

The present invention provides a mouse shell with cooling touch, which includes a plastic material and a thermally conductive material, and the thermally conductive material is selected from the group consisting of thermally conductive powders, a thermally conductive object and a combination thereof. The thermally conductive powders are dispersed in the plastic material. The thermally conductive object is covered by the plastic material, or the thermally conductive object is attached beneath the plastic material. The thermally conductive powders are selected from the group consisting of metal powders, alloy powders, ceramic powders and combinations thereof. The thermally conductive object is selected from a metal object, an alloy object, a ceramic object and combinations thereof.

In some embodiments of the present disclosure, the thermally conductive object is a thermally conductive sheet having a shape of the mouse shell.

In some embodiments of the present disclosure, the thermally conductive object has one or more through holes configured to correspond to one or more light sources.

In some embodiments of the present disclosure, the plastic material is fully transparent or translucent.

In some embodiments of the present disclosure, the mouse shell further includes a metallic appearance layer covering the plastic material.

The present disclosure also includes a method of manufacturing a mouse shell with cooling touch, which includes: performing an insert injection molding process, so that a plastic material covers a thermally conductive object to form a mouse shell, or, attaching a thermally conductive object to and beneath a plastic material to form a mouse shell; in which the thermally conductive object is selected from the group consisting of a metal object, an alloy object, a ceramic object, and combinations thereof.

In some embodiments of the present disclosure, the method further includes: performing a metallic appearance treatment on the mouse shell to form a metallic appearance layer on the plastic material of the mouse shell.

In some embodiments of the present disclosure, the metallic appearance treatment includes evaporation, sputtering, bronzing, plastic plating, spray painting, transfer printing, in-mold decoration techniques, or combinations thereof.

In some embodiments of the present disclosure, the thermally conductive object is a thermally conductive sheet having a shape of the mouse shell.

### BRIEF DESCRIPTION OF THE DRAWINGS

Aspects of the present invention are best understood from the following embodiments, read in conjunction with accompanying drawings. However, it should be understood that in accordance with common practice in the industry, various features have not necessarily been drawn to scale. Indeed, shapes of the various features may be suitably adjusted for clarity, and dimensions of the various features may be arbitrarily increased or decreased.

FIG. 1 is a three-dimensional schematic diagram of a mouse shell with cooling touch according to an embodiment of the present invention.

FIG. 2 is a schematic cross-sectional view of a mouse shell with cooling touch according to an embodiment of the present invention.

FIG. 3 is a schematic cross-sectional view of a mouse shell with cooling touch according to an embodiment of the present invention.

FIG. 4 is a schematic exploded perspective view of a mouse shell with cooling touch according to an embodiment of the present invention.

FIG. 5 is a schematic cross-sectional view of a mouse shell with cooling touch according to an embodiment of the present invention.

FIG. 6 is a schematic cross-sectional view of a mouse shell with cooling touch according to an embodiment of the present invention.

FIG. 7 is a schematic cross-sectional view of a mouse shell with cooling touch according to an embodiment of the present invention.

FIG. 8 is a schematic cross-sectional view of a mouse shell with cooling touch according to an embodiment of the present invention.

### DETAIL DESCRIPTION OF THE PREFERRED EMBODIMENT

The advantages and features of the present invention and the method for achieving the same will be described in more detail with reference to exemplary embodiments and accompanying drawings to make it easier to understand. However, the present invention can be implemented in different forms and should not be construed as being limited to the embodiments set forth herein. On the contrary, for those skilled in the art, the provided embodiments will make this disclosure more thorough, comprehensive and complete to convey the scope of the present invention.

The spatially relative terms in the text, such as “beneath” and “over”, are used to facilitate the description of the relative relationship between one element or feature and another element or feature in the drawings. The true meaning of the spatially relative terms includes other orientations. For example, when the drawing is flipped up and down by 180 degrees, the relationship between the one element and the other element may change from “beneath” to “over.” The spatially relative descriptions used herein should be interpreted the same.

As mentioned in background of the invention, existing mouse shells are mostly made of plastic materials, which do not have cooling touch. However, some users may feel stuffy and uncomfortable when using the mouse. Therefore, there is a need for a mouse with cooling touch to solve the above issues. Accordingly, the present invention provides a mouse shell with cooling touch to solve the above issues. Various embodiments of the mouse shell of the present invention will be described in detail below.

The mouse shell of the present invention includes a plastic material and a thermally conductive material, and the thermally conductive material is selected from the group consisting of thermally conductive powders, a thermally conductive object, and a combination thereof.

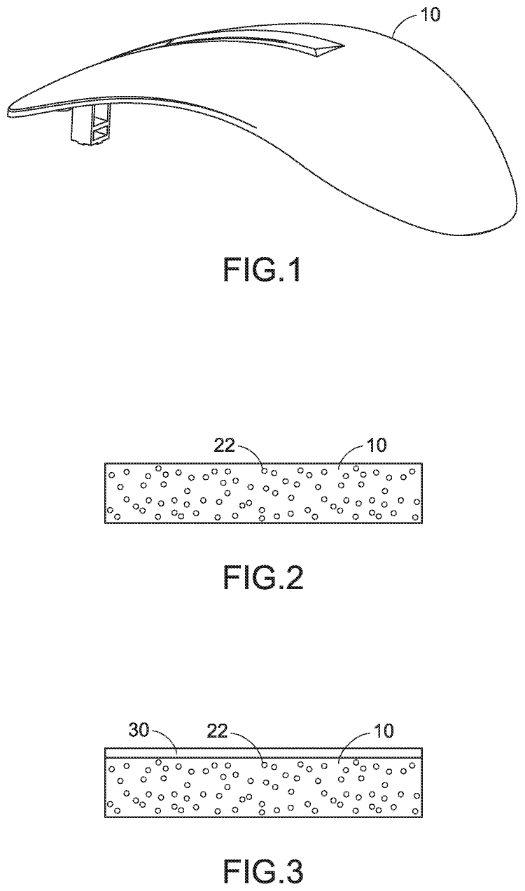

FIG. 1 is a three-dimensional schematic diagram of a mouse shell with cooling touch according to an embodiment of the present invention. FIG. 2 is a schematic cross-sectional view of a mouse shell with cooling touch according to an embodiment of the present invention. As shown in FIG. 1 and FIG. 2, the mouse shell includes a plastic material 10 and a thermally conductive material, and the thermally conductive material is thermally conductive powders 22 dispersed in the plastic material 10. The thermally conductive powders 22 are selected from the group consisting of metal powders, alloy powders, ceramic powders, and combinations thereof. A metal of the metal powders may be, for example, silver, aluminum, copper, iron or steel, but is not limited thereto. An alloy of the alloy powders may be, for example, an alloy containing silver, aluminum, copper, iron and/or steel, but is not limited thereto. A ceramic of the ceramic powders can be, for example, aluminum oxide, magnesium oxide, zinc oxide, aluminum nitride, boron nitride, silicon carbide or silicon dioxide, but is not limited thereto. In some embodiments, a particle size of the thermally conductive powders 22 is nano-scale or micro-scale. In other embodiments, the thermally conductive powders may be located on a surface of the plastic material, that is, portions of some of the thermally conductive powders may be exposed to the outside (not shown).

FIG. 3 is a schematic cross-sectional view of a mouse shell with cooling touch according to an embodiment of the present invention. In some embodiments, as shown in FIG. 3, the mouse shell further includes a metallic appearance layer 30 covering the plastic material 10. As such, the mouse shell of FIG. 3 can have both a metallic appearance and the cooling touch.

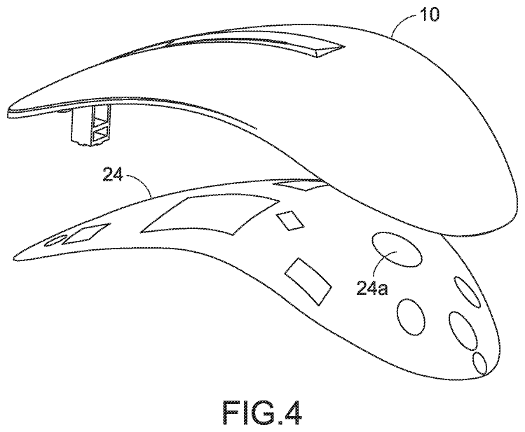

FIG. 4 is a schematic exploded perspective view of a mouse shell with cooling touch according to an embodiment of the present invention. As shown in FIG. 4, the mouse shell includes a plastic material 10 and a thermally conductive material, and the thermally conductive material is a thermally conductive object 24. In some embodiments, the thermally conductive object 24 is a thermally conductive sheet having a shape of the mouse shell. The thermally conductive object 24 is selected from the group consisting of a metal object, an alloy object, a ceramic object, and combinations thereof. A metal of the metal object may be, for example, silver, aluminum, copper, iron or steel, but is not limited thereto. An alloy of the alloy object may be, for example, an alloy containing silver, aluminum, copper, iron and/or steel, but is not limited thereto. A ceramic of the ceramic object can be, for example, aluminum oxide, magnesium oxide, zinc oxide, aluminum nitride, boron nitride, silicon carbide, silicon dioxide, but is not limited thereto.

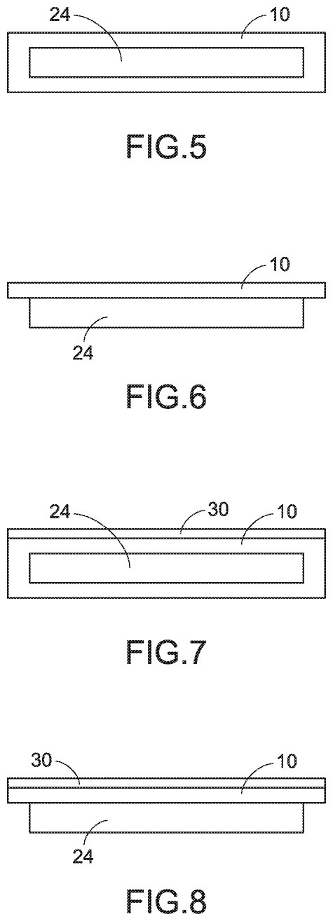

FIG. 5 is a schematic cross-sectional view of a mouse shell with cooling touch according to an embodiment of the present invention. As shown in FIG. 4 and FIG. 5, the thermally conductive object 24 is covered by the plastic material 10. In some embodiments, a thickness of the thermally conductive object 24 is greater than or equal to a thickness of the plastic material 10, but the invention is not limited thereto. In some embodiments, the thermally conductive object 24 has a thickness in a range of from 0.3 mm to 1.0 mm.

FIG. 6 is a schematic cross-sectional view of a mouse shell with cooling touch according to an embodiment of the present invention. As shown in FIG. 4 and FIG. 6, the thermally conductive object 24 is attached beneath the plastic material 10. In some embodiments, the thermally conductive object 24 is in direct contact with a lower surface of the plastic material 10, or there is an adhesive layer (not shown) between the thermally conductive object 24 and the plastic material 10. In some embodiments, a thickness of the thermally conductive object 24 is greater than or equal to a thickness of the plastic material 10, but the invention is not limited thereto. In some embodiments, the thermally conductive object 24 has a thickness in a range of from 0.3 mm to 1.0 mm.

FIG. 7 is a schematic cross-sectional view of a mouse shell with cooling touch according to an embodiment of the present invention. Compared to FIG. 5, the mouse shell of FIG. 7 further includes a metallic appearance layer 30 covering the plastic material 10. As such, the mouse shell of FIG. 7 can have both a metallic appearance and the cooling touch.

FIG. 8 is a schematic cross-sectional view of a mouse shell with cooling touch according to an embodiment of the present invention. Compared with FIG. 6, the mouse shell of FIG. 8 further includes a metallic appearance layer 30 covering the plastic material 10. As such, the mouse shell of FIG. 8 can have both a metallic appearance and the cooling touch.

It should be noted that the present invention is not limited to the above-mentioned embodiments. For example, the plastic material 10 and the thermally conductive powders 22 of FIG. 2 can be combined with the thermally conductive object 24 of FIG. 4. For example, the plastic material 10 and the thermally conductive powders 22 of FIG. 2 can be used to replace the plastic material 10 of FIG. 5 or FIG. 6 to further improve thermal conductivity of the mouse shell.

In some embodiments, as shown in FIG. 4, the thermally conductive object 24 has one or more through holes 24a configured to correspond to one or more light sources. In some embodiments, the plastic material 10 is fully transparent or translucent. As such, light emitted by the light source(s) disposed inside the mouse can pass through the through hole(s) 24a of the thermally conductive object 24 and the plastic material 10, so that the mouse has a backlight effect. In some embodiments, the metallic appearance layer 30 shown in FIG. 7 or FIG. 8 is a light transmitting layer, or laser engraving is performed on the position(s) of the metallic appearance layer 30 corresponding to the through hole(s) 24a, so that light emitted by the light source(s) disposed inside the mouse can be exposed to the outside after passing through the through hole(s) 24a of the thermally conductive object 24 and the plastic material 10, so that the mouse has a backlight effect.

The present invention provides a method for manufacturing a mouse shell with cooling touch, which includes: performing an insert injection molding process, so that a plastic material covers a thermally conductive object to form the mouse shell shown in FIG. 5. In some embodiments, referring to FIG. 5, the insert injection molding process includes following steps: placing a thermally conductive object 24 in a mold (not shown); injecting a raw plastic material into a space of the mold; maintaining the raw plastic material at a curing temperature for a certain period of time to shape the raw plastic material to form the mouse shell including the thermally conductive object 24 and the plastic material 10. The thermally conductive object 24 is selected from the group consisting of a metal object, an alloy object, a ceramic object, and combinations thereof. In some embodiments, the thermally conductive object 24 is a thermally conductive sheet having a shape of the mouse shell.

The present invention further provides a method for manufacturing a mouse shell with cooling touch, which includes: attaching a thermally conductive object to and beneath a plastic material to form the mouse shell shown in FIG. 6. In some embodiments, the thermally conductive object is attached beneath the plastic material through an adhesive layer. The thermally conductive object is selected from the group consisting of a metal object, an alloy object, a ceramic object, and combinations thereof. In some embodiments, the thermally conductive object is a thermally conductive sheet having a shape of the mouse shell.

The present invention further provides a method for manufacturing a mouse shell with cooling touch, which includes: mixing thermally conductive powders with a raw plastic material, and then performing a suitable process (e.g., an injection molding process) to form the mouse shell shown in FIG. 2. The thermally conductive powders are selected from the group consisting of metal powders, alloy powders, ceramic powders, and combinations thereof.

In some embodiments, referring to FIG. 3, FIG. 7 or FIG. 8, the above-mentioned method for manufacturing the mouse shell with cooling touch further includes: performing a metallic appearance treatment on the mouse shell to form a metallic appearance layer 30 on the plastic material 10 of the mouse shell. In some embodiments, the metallic appearance treatment includes evaporation, sputtering, bronzing, plastic plating (e.g., vacuum plating (e.g., non conductive vacuum metalization (NCVM)) or water plating), spray painting, transfer printing (e.g. thin film transfer printing), in mold decoration (IMD) (e.g., in mold label (IML) or in mold film (IMF)) or combinations thereof, but the present invention is not limited thereto. In some embodiments, evaporation, sputtering, or a combination thereof may be used to form a light transmitting metallic appearance layer 30.

However, the above are only the preferred embodiments of the present invention, and should not be used to limit the scope of implementation of the present invention, that is, simple equivalent changes and modifications made in accordance with claims and description of the present invention are still within the scope of the present invention. In addition, any embodiment of the present invention or claim does not need to achieve all the objectives or advantages disclosed in the present invention. In addition, the abstract and the title are not used to limit the scope of claims of the present invention.

What is claimed is:

1. A mouse shell with cooling touch, comprising a plastic material and a thermally conductive material, the thermally conductive material being selected from the group consisting of thermally conductive powders, a thermally conductive object and a combination thereof; the thermally conductive powders being dispersed in the plastic material; the thermally conductive object being covered by the plastic material, or the thermally conductive object being attached beneath the plastic material; wherein the thermally conductive powders are selected from the group consisting of metal powders, alloy powders, ceramic powders and combinations thereof, and the thermally conductive object is selected from the group consisting of a metal object, an alloy object, a ceramic object, and combinations thereof.

2. The mouse shell of claim 1, wherein the thermally conductive object is a thermally conductive sheet having a shape of the mouse shell.

3. The mouse shell of claim 1, wherein the thermally conductive object has one or more through holes configured to correspond to one or more light sources.

4. The mouse shell of claim 3, wherein the plastic material is fully transparent or translucent.

5. The mouse shell of claim 1, further comprising a metallic appearance layer covering the plastic material.

6. The mouse shell of claim 1, wherein a thickness of the thermally conductive object is greater than or equal to a thickness of the plastic material.

7. A method of manufacturing a mouse shell with cooling touch, comprising:
performing an insert injection molding process, so that a plastic material covers a thermally conductive object to form a mouse shell, or, attaching a thermally conductive object to and beneath a plastic material to form a mouse shell; wherein the thermally conductive object is selected from the group consisting of a metal object, an alloy object, a ceramic object, and combinations thereof.

8. The method of claim 7, further comprising:
performing a metallic appearance treatment on the mouse shell to form a metallic appearance layer on the plastic material of the mouse shell.

9. The method of claim 8, wherein the metallic appearance treatment comprises evaporation, sputtering, bronzing, plastic plating, spray painting, transfer printing, in-mold decoration techniques, or combinations thereof.

10. The method of claim 7, wherein the thermally conductive object is a thermally conductive sheet having a shape of the mouse shell.
